(19) United States
(12) Patent Application Publication
(10) Pub. No.: US 2025/0393349 A1
(43) Pub. Date: Dec. 25, 2025

(54) DISPLAY PANEL AND DISPLAY DEVICE

(71) Applicant: Hubei Yangtze Industrial Innovation Center Of Advanced Display Co., Ltd., Wuhan (CN)

(72) Inventor: Xiao CHI, Wuhan (CN)

(73) Assignee: Hubei Yangtze Industrial Innovation Center Of Advanced Display Co., Ltd., Wuhan (CN)

(21) Appl. No.: 18/900,973

(22) Filed: Sep. 30, 2024

(30) Foreign Application Priority Data
Jun. 20, 2024 (CN) 202410804319.3

(51) Int. Cl. H01L 33/62; H01L 25/075

(52) U.S. Cl. CPC H10H 20/857; H01L 25/0753

(57) ABSTRACT

Embodiments of the present application provides a display panel and a display device, the display panel comprises a plurality of light-emitting areas and non-light-emitting areas located between adjacent light-emitting areas, and also a device layer, first conductor portions, second conductor portions, and light-blocking structures, wherein the first conductor portions are at least partially located in the light-emitting areas and arranged on the light-emitting side of the device layer, the second conductor portions are located in the non-light-emitting areas and arranged on the light-emitting side of the device layer, and the first conductor portions are insulated from the second conductor portions; the light-blocking structures are arranged on the light-emitting side of the device layer and configured to be attracted or repelled by the first conductor portions or the second conductor portions to transfer between the light-emitting areas and the non-light-emitting areas.

### CROSS-REFERENCE TO RELATED APPLICATION

The present application claims priority to Chinese Patent Application No. 202410804319.3 filed on Jun. 20, 2024, and titled “DISPLAY PANEL AND DISPLAY DEVICE”, which is incorporated herein by reference in its entirety.

### TECHNICAL FIELD

The present application relates to the technical field of display apparatus, and in particular to a display panel and a display device.

### BACKGROUND

With the development of science and technology, there has been a great progress made in the field of display panel, and people's requirements for display panels are also increasing steadily. How to further improve the service life and display effect of display panels has become one of the key research directions of major manufacturers.

### SUMMARY

In a first aspect, embodiments of the present application provides a display panel, comprising: a plurality of light-emitting areas, and non-light-emitting areas located between adjacent ones of the light-emitting areas; a device layer; at least one first conductor portion, at least partially located in the light-emitting areas and arranged on a light-emitting side of the device layer; at least one second conductor portion, located in the non-light-emitting areas and arranged on the light-emitting side of the device layer, the at least one second conductor portion being insulated from the at least one first conductor portion; at least one light-blocking structure, disposed on the light-emitting side of the device layer and configured to be attracted or repelled by the at least one first conductor portion and the at least one second conductor portion to transfer between the light-emitting areas and the non-light-emitting areas.

In a second aspect, embodiments of the present application provides a display device comprising a display panel comprising: a plurality of light-emitting areas, and non-light-emitting areas located between adjacent ones of the light-emitting areas; a device layer; at least one first conductor portion, at least partially located in the light-emitting areas and arranged on a light-emitting side of the device layer; at least one second conductor portion, located in the non-light-emitting areas and arranged on the light-emitting side of the device layer, the at least one second conductor portion being insulated from the at least one first conductor portion; at least one light-blocking structure, disposed on the light-emitting side of the device layer and configured to be attracted or repelled by the at least one first conductor portion and the at least one second conductor portion to transfer between the light-emitting areas and the non-light-emitting areas.

### BRIEF DESCRIPTION OF THE DRAWINGS

FIG. 1 is a partial schematic structural diagram of part of light-emitting areas of a display panel provided by an embodiment of the present application;

FIG. 2 is a cross-sectional schematic structural diagram along A-A in FIG. 1 in an anti-peeping mode;

FIG. 3 is a cross-sectional schematic structural diagram along A-A in FIG. 1 in a large-viewing angle mode;

FIG. 4 is another partial schematic structural diagram of part of light-emitting areas of a display panel provided by an embodiment of the present application;

FIG. 5 is another partial schematic structural diagram of part of light-emitting areas of a display panel provided by an embodiment of the present application;

FIG. 6 is another partial schematic structural diagram of part of light-emitting areas of a display panel provided by an embodiment of the present application;

FIG. 7 is another cross-sectional schematic structural diagram of a display panel provided in an embodiment of the present application;

FIG. 8 is another cross-sectional schematic structural diagram of a display panel provided in an embodiment of the present application;

FIG. 9 is another cross-sectional schematic structural diagram of a display panel provided in an embodiment of the present application;

FIG. 10 is another partial schematic structural diagram of part of light-emitting areas of a display panel provided by an embodiment of the present application;

FIG. 11 is another partial schematic structural diagram of part of light-emitting areas of a display panel provided by an embodiment of the present application;

FIG. 12 is another partial schematic structural diagram of part of light-emitting areas of a display panel provided by an embodiment of the present application;

FIG. 13 is another cross-sectional schematic structural diagram of a display panel provided in an embodiment of the present application;

FIG. 14 is another cross-sectional schematic structural diagram of a display panel provided in an embodiment of the present application;

FIG. 15 is another cross-sectional schematic structural diagram of a display panel provided in an embodiment of the present application;

FIG. 16 is another cross-sectional schematic structural diagram of a display panel provided in an embodiment of the present application;

FIG. 17 is another cross-sectional schematic structural diagram of a display panel provided in an embodiment of the present application;

FIG. 18 is a schematic structural diagram of a display device provided in an embodiment of the present application.

### REFERENCE NUMERALS

100. display panel; 200. display device;
10. device layer; 11. light-emitting side; 12. light-emitting structure; 12a. first light-emitting structure; 12b. second light-emitting structure; 13. anode layer; 14. light-emitting material layer; 15. cathode layer;
20. first conductor portion; 21. first sub-portion; 211. first branch portion; 212. second branch portion; 22. second sub-portion;
30. second conductor portion; 31. third sub-portion;

40. light-blocking structure; 41. electrophoretic particles;
51. first potential portion; 52. second potential portion;
60. light-transmitting layer; 61. first surface; 62. recessed portion; 62a. first recessed portion; 62b. second recessed portion;
T. thin film transistor; L. branch structure;
A1. light-emitting area; A2. non-light-emitting area; A3. repeated zone;
X. first direction; Y. second direction; Z. thickness direction.

### DETAILED DESCRIPTION

The features and exemplary embodiments of various aspects of the present application will be described in detail below. In order to make the purpose, technical solutions and advantages of the present application more clear, the present application will be further described in detail below in conjunction with the accompanying drawings and specific embodiments. It should be understood that the specific embodiments described here are only intended to explain the application, rather than limit the application. For the skilled in the art, the application can be implemented without the need for some of these specific details. The following description of the embodiments is only to provide a better understanding of the application by illustrating the example of the application.

It should be noted that, in this article, relational terms such as first and second, etc. are only used to distinguish one entity or operation from another entity or operation, and do not necessarily require or imply any such actual relationship or order between these entities or operations. Moreover, the terms “comprise”, “comprising” or any other variants thereof are intended to cover non-exclusive inclusion, so that a process, method, article or device including a series of elements comprises not only those elements, but also other elements not explicitly listed, or also comprises elements inherent to such process, method, article or device. In the absence of further restrictions, the elements defined by the statement “comprise . . . ” do not exclude the existence of other identical elements in the process, method, article or device including the elements.

It is obvious to the skilled in the art that various modifications and changes can be made in this application without departing from the spirit or scope of this application. Therefore, this application is intended to cover modifications and changes of this application that fall within the scope of the corresponding claims (technical solutions claimed for protection) and their equivalents. It should be noted that the implementation methods provided in the embodiments of this application can be combined with each other without contradiction.

Display panels can usually be used in a variety of fields and environments, and users have different requirements for display panels in different situations. In some cases, such as in the field of in-vehicle displays, in order to improve driving safety, it is usually necessary to control the optical path of the display panel to achieve an anti-peep (anti-interference) effect, reduce the impact of the display screen on the driver, and reduce the risk of causing safety hazards.

The display panel usually comprises light-emitting areas corresponding to the sub-pixels, and non-light-emitting areas between adjacent light-emitting areas. In the related art, in order to reduce the impact of the display image on the driver, a light-blocking pattern is provided in the display panel. The light-blocking pattern has a certain width and thickness, and is usually provided corresponding to the light-emitting areas of the display panel, so as to absorb part of the light with a large viewing angle with the help of the light-blocking pattern, thereby meeting the anti-peeping needs. However, this design will lead to a decrease in the corresponding light-emitting efficiency of the display panel, and will also have an adverse effect on the service life of the display panel.

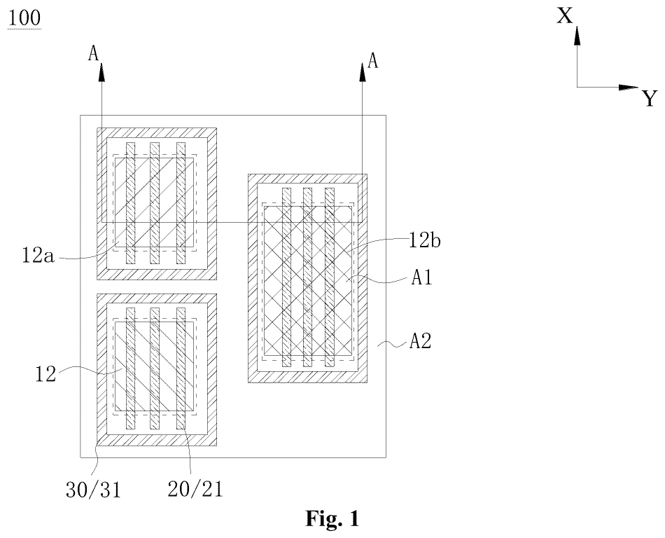

In view of the above problems, referring to FIGS. 1 to 3, an embodiment of the present application provides a display panel 100, which comprises a plurality of light-emitting areas A1 and non-light-emitting areas A2 located between adjacent light-emitting areas A1. The display panel 100 further comprises a device layer 10, first conductor portions 20, second conductor portions 30, and light-blocking structures 40. The first conductor portions 20 are at least partially located in the light-emitting areas A1 and are disposed on a light-emitting side 11 of the device layer 10. The second conductor portions 30 are located in the non-light-emitting areas A2 and are disposed on the light-emitting side 11 of the device layer 10. The first conductor portions 20 are insulated from the second conductor portions 30. The light-blocking structures 40 are disposed on the light-emitting side 11 of the device layer 10. The light-blocking structures 40 are configured to be attracted or repelled by the first conductor portions 20 or the second conductor portions 30 to transfer between the light-emitting areas A1 and the non-light-emitting areas A2.

The display panel 100 may be a device for converting a digital signal into a visible image. The display panel 100 comprises a plurality of light-emitting areas A1 and non-light-emitting areas A2. The light-emitting areas A1 are areas in the display panel 100 that can emit light to realize the light-emitting function. The non-light-emitting areas A2 are areas in the display panel 100 that do not emit light. The plurality of light-emitting areas A1 may be arranged in a single or multiple directions at intervals, and the non-light-emitting areas A2 are located between adjacent light-emitting areas A1. At least some of the light-emitting areas A1 may be used to emit light of different colors. For example, the plurality of light-emitting areas A1 comprise blue light-emitting areas for emitting blue light, green light-emitting areas for emitting green light, and red light-emitting areas for emitting red light. In FIG. 1, the light-emitting areas A1 are indicated by dotted boxes, the non-light-emitting areas A2 are located outside the light-emitting areas A1, and the non-light-emitting areas A2 at adjacent positions of different light-emitting areas A2 may be connected and arranged as a whole. It should be noted that the non-light-emitting areas A2 may also be located between the light-emitting areas A1 and the boundaries of the display panel.

The device layer 10 may comprise a plurality of film layer structures stacked in layers, and the device layer 10 may comprise different film layer structures according to the type of the display panel 100. For example, if the display panel 100 is a liquid crystal display panel, the device layer 10 may comprise a pixel electrode layer, a liquid crystal layer, and a common electrode layer. If the display panel 100 is an organic light-emitting display panel, the device layer 10 may comprise an anode layer 13, a light-emitting material layer 14, and a cathode layer 15 stacked in layers. Furthermore, the device layer 10 may adopt a top emission light-emitting mode, or a bottom emission light-emitting mode, and no matter which light-emitting mode is adopted, the light-emitting side 11 of the device layer 10 is located on a side of the device layer 10 facing the light-emitting surface of the display panel 100.

The first conductor portions 20 and the second conductor portions 30 are conductor structures located on the light-emitting side 11 of the device layer 10. Embodiments of the present application do not limit the material composition of the first conductor portions 20 and the second conductor portions 30. They may comprise the same material or different materials. Exemplarily, at least one of the first conductor portions 20 and the second conductor portions 30 may comprise a metal material; and/or at least one of the first conductor portions 20 and the second conductor portions 30 may comprise a transparent conductive material such as indium tin oxide.

The first conductor portions 20 are at least partially located in the light-emitting areas A1, that is, the first conductor portions 20 at least partially overlap with the light-emitting areas A1 in the thickness direction Z of the display panel. The first conductor portions 20 may be completely located in the light-emitting areas A1, or the first conductor portions 20 may be partially located in the light-emitting areas A1 and partially located in the non-light-emitting areas A2. The second conductor portions 30 are located in the non-light-emitting areas A2, that is, projections of the second conductor portions 30 in the thickness direction Z of the display panel are located within projections of the non-light-emitting areas A2 in the thickness direction Z of the display panel. The specific shapes and sizes of the first conductor portions 20 and the second conductor portions 30 are not limited in the embodiment of the present application.

The light-blocking structures 40 are structures located on the light-emitting side 11 of the device layer 10 and capable of absorbing light. The light-blocking structures 40 have certain electricity and can be attracted or repelled by the first conductor portions 20 or the second conductor portions 30 to transfer between the light-emitting areas A1 and the non-light-emitting areas A2, thereby satisfying the switching of the display panel in different working modes.

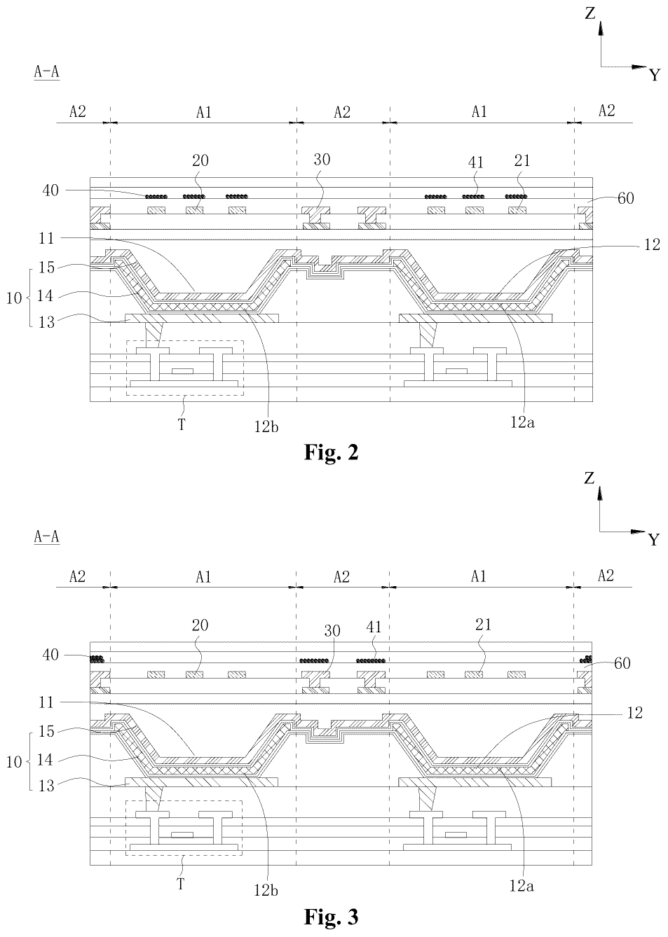

Specifically, taking for example that the light-blocking structures 40 are positively charged structures, as shown in FIG. 2 and FIG. 3, when the light-blocking structures 40 are located in the non-light-emitting areas A2, the second conductor portions 30 can be controlled to be at positive voltage potentials so that the second conductor portions 30 exert repulsive force on the light-blocking structures 40. The first conductor portions 20 are controlled to be at negative voltage potentials so that the first conductor portions 20 exert attractive force on the light-blocking structures 40. Under the joint action of the first conductor portions 20 and the second conductor portions 30, the light-blocking structures 40 are transferred from the non-light-emitting areas A2 to the positions corresponding to the first conductor portions 20 in the light-emitting areas A1. In this case, the display panel 100 is in an anti-peep (anti-interference) mode. The existence of the light-blocking structures 40 can divide the light-emitting areas A1 each into a plurality of sub-areas, and part of the large-viewing-angle light emitted from sub-areas each can be absorbed and shielded by the light-blocking structures 40, thereby realizing the anti-peep (anti-interference) function.

Similarly, when the light-blocking structures 40 are located in the light-emitting areas A1, the first conductor portions 20 can be controlled to have positive voltage potentials, so that the first conductor portions 20 apply repulsive force to the light-blocking structures 40. The second conductor portions 30 can be controlled to have negative voltage potentials, so that the second conductor portions 30 apply attractive force to the light-blocking structures 40. Under the joint action of the first conductor portions 20 and the second conductor portions 30, the light-blocking structures 40 are transferred from the light-emitting areas A1 to the positions corresponding to the second conductor portions 30 in the non-light-emitting area A2. In this case, the display panel 100 is in a large-viewing angle mode, the light-blocking structures 40 absorb a small amount of light, and at least part of the large-viewing angle light emitted from the light-emitting areas A1 can be emitted from the display panel, thereby realizing a large-viewing angle display function.

It should be noted that the presence of the first conductor portions 20 and the second conductor portions 30 can not only realize the transfer of the light-blocking structures 40 between the light-emitting areas A1 and the non-light-emitting areas A2, but also be used to limit the position of the light-blocking structures 40. Specifically, in the anti-peeping mode, the first conductor portions 20 will exert attractive forces on the light-blocking structures 40, so that the light-blocking structures 40 are located close to the first conductor portions 20 in the light-emitting areas A1, and the continued presence of the attractive forces can also limit the positions of the light-blocking structures 40 to remain fixed. Optionally, in the anti-peeping mode, the light-blocking structures 40 and the first conductor portions 20 can be overlapped in the thickness direction Z of the display panel. The large-viewing angle mode is in a similar way, and the embodiments of the present application will not be repeated.

Moreover, the embodiment of the present application does not limit the specific positional relationship of the first conductor portions 20, the second conductor portions 30 and the light-blocking structures 40 in the thickness direction Z of the display panel 100. For example, the first conductor portions 20 and the second conductor portions 30 can be located in the same film layer, or in different film layers, the light-blocking structures 40 can be located on a side of at least one of the first conductor portions 20 and the second conductor portions 30 facing the device layer 10, or on a side of at least one of the first conductor portions 20 and the second conductor portions 30 away from the device layer 10. As long as the first conductor portions 20, the second conductor portions 30 and the light-blocking structures 40 are all located on the light exit side 11 of the device layer 10, and the light-blocking structures 40 can move under the attraction or repulsion of the first conductor portions 20 and the second conductor portions 30, it will be sufficient.

In some optional embodiments, the display panel 100 comprises a light-transmitting layer 60, and the light-blocking structures 40 are located on a side of the light-transmitting layer 60 away from the device layer 10. Further optionally, the light-transmitting layer 60 can be reused as an insulating layer covering at least one of the first conductor portions 20 and the second conductor portions 30.

In the embodiment of the present application, the light-blocking structures 40 can realize the transfer between the light-emitting areas A1 and the non-light-emitting areas A2 under the control of the first conductor portions 20 and the second conductor portions 30, so that the display panel can switch between different modes, which has strong flexibility. And when the light-blocking structures 40 are located in the non-light-emitting areas A2, the light-blocking structures 40 have little effect on the light-emitting efficiency of the light-emitting areas A1, thus there is no need to increase the display brightness by increasing the driving circuit, which helps to improve the display effect and service life of the display panel 100.

It should be noted that the display panel 100 provided in the embodiments of the present application can be applied to the field of vehicle-mounted display, or can be applied to other fields, such as in the field of mobile terminals such as mobile phones. In order to protect the privacy and security of users, the display panel 100 provided in the embodiment of the present application can be used. The embodiments of the present application do not specifically limit the specific application scenario of the display panel 100.

Moreover, in addition to the film layer structures mentioned above, the display panel 100 may further comprise other film layer structures. The specific film layer composition of the display panel 100 is not limited in the embodiments of the present application. Optionally, the display panel 100 further comprises a plurality of conductor layers and semiconductor layers located on the side of the device layer 10 away from the light-blocking structures 40, and an insulating layer located between two adjacent conductor layers or between a conductor layer and a semiconductor layer that are adjacent. Further, the display panel may comprise a thin film transistor T, which comprises a conductor structure located in the conductor layer, and an active structure located in the semiconductor layer.

In some embodiments, as shown in FIGS. 1 to 3, the light-emitting areas A1 comprises light-emitting structures 12, and the first conductor portions 20 comprises first sub-portions 21. In the thickness direction Z of the display panel, the first sub-portions 21 are overlapped with the light-emitting structures 12.

The light-emitting structure 12 is a structure for achieving the light-emitting effect in the display panel 100 and is located in the light-emitting area A1. The light-emitting structure 12 can be composed of multiple film layer structures. Taking the organic light-emitting display panel as an example, the light-emitting structure 12 can comprise a light-emitting material between the anode and the cathode in the light-emitting area A1, a hole transport layer, an electron transport layers, etc. Taking the liquid crystal display panel as an example, the light-emitting structure can comprise a liquid crystal material in the light-emitting area (opening area).

The first sub-portion 21 is at least part of the structure in the first conductor portion 20. In the thickness direction Z of the display panel 100, the first sub-portions 21 overlap with the light-emitting structures 12, that is, in the thickness direction Z of the display panel 100, projections of the first sub-portions 21 may be completely located within projections of the light-emitting structures 12, or the projections of the first sub-portions 21 may be partially located within the projections of the light-emitting structures 12 and partially located outside the projections of the light-emitting structures 12.

It should be noted that, for one light-emitting structure 12, it can overlap with only one first sub-portion 21, or it can overlap with multiple first sub-portions 21 at the same time. When a light-emitting structure 12 overlaps with multiple first sub-portions 21 at the same time, the potentials of the multiple first sub-portions 21 can be equal or different.

In the embodiment of the present application, the first sub-portions 21 are overlapped with the light-emitting structures 12, so that the light-blocking structures 40 can be attracted to the light-emitting areas A1 by the first sub-portions 21, and the display panel 100 can achieve the anti-peeping function. Since in the anti-peeping mode, the light-blocking structures 40 are often distributed in positions close to the first sub-portions 21, on this basis, the sizes and shapes corresponding to the first sub-portions 21 can be adjusted to achieve the control of the morphology of the light-blocking structures 40 in the anti-peeping mode, which helps to improve the anti-peeping effect of the display panel 100 and has strong flexibility.

In some embodiments, as shown in FIGS. 1 to 3, a plurality of first sub-portions 21 overlap with the same light-emitting structure 12 in the thickness direction Z of the display panel 100.

It should be noted that the size, shape and extending direction of different first sub-portions 21 may be the same or different. Also, at the same time, the potentials of different first sub-portions 21 overlapping with the same light-emitting structure 12 may be the same or different, which is not limited in the present embodiment.

In the embodiment of the present application, multiple first sub-portions 21 are simultaneously arranged corresponding to the same light-emitting structure 12, so that under the common attraction or repulsion of the multiple first sub-portions 21, a rate at which the light-blocking structure 40 is transferred to or leaves the light-emitting area A1 can be accelerated, thereby improving the switching efficiency of the display panel 100 in different modes. In addition, in the anti-peeping mode, the presence of multiple first sub-portions 21 enables the light-blocking structures 40 to be arranged at different positions in the same light-emitting area A1, thereby helping to divide the single light-emitting area A1 into more sub-areas, and using the light-blocking structures 40 to absorb the large-viewing-angle light emitted by each single sub-area, improving the anti-peeping effect of the display panel 100.

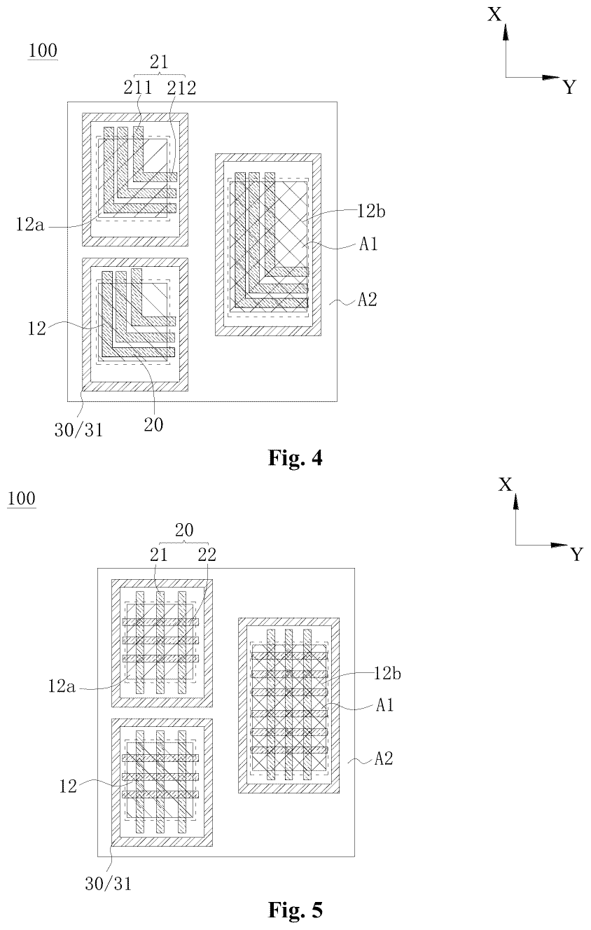

In some embodiments, as shown in FIG. 1, a plurality of first sub-portions 21 extend along the first direction X and are arranged side by side in the second direction Y; or as shown in FIG. 4, the first sub-portions 21 comprise first branch portions 211 extending along the first direction X and second branch portions 212 extending along the second direction Y. The first branch portions 211 each are formed integrally with and electrically connected with a second branch portions 212; the first direction X, the second direction Y, and the thickness direction of the display panel 100 intersect each other. Optionally, the first direction X, the second direction Y, and the thickness direction of the display panel 100 are arranged perpendicularly to each other.

In combination with the above content, it can be known that the layout of the first sub-portions 21 often determines the distribution form of the light-blocking structures 40 in the anti-peeping mode. On this basis, the first sub-portions 21 can be set as strip structures extending in a single direction, so that the light-blocking structures 40 in the anti-peeping mode can comprise strip structures extending along the first direction X. Alternatively, the first sub-portions 21 can be set to comprise first branch portions 211 and second branch portions 212 with different extending directions, so that the light-blocking structures 40 in the anti-peeping mode can comprise strip structures extending in multiple directions, thereby meeting the anti-peeping needs in different situations, with strong flexibility and practicality.

In some embodiments, referring to FIG. 5, the first conductor portions 20 comprises first sub-portions 21 extending along the first direction X, and second sub-portions 22 extending along the second direction Y. In the thickness direction of the display panel 100, the first sub-portions 21 and the second sub-portions 22 overlap with the same light-emitting structure 12.

The first sub-portion 21 and the second sub-portion 22 are different parts of one first conductor portion 20, and they extend in different directions, but overlap with a same light-emitting structure 12. The positional relationship of the first sub-portions 21 and the second sub-portions 22 in the thickness direction Z of the display panel 100 is not limited in the embodiment of the present application. Exemplarily, the first sub-portions 21 and the second sub-portions 22 may be located in the same film layer, or the first sub-portions 21 may be located on a side of the second sub-portions 22 facing or away from the device layer 10. Furthermore, the first sub-portions 21 may be connected with the second sub-portions 22, or the first sub-portions 21 may be insulated from the second sub-portions 22.

The layout of the first conductor portions 20 in the embodiment of the present application helps to further improve the anti-peeping effect. Specifically, take for example that the display panel 100 is applied to the field of vehicle-mounted display, and the second direction Y is the width direction of the vehicle, and the first direction X is the height direction of the vehicle. The first conductor portions 20 comprises first sub-portions 21 extending along the first direction X, and second sub-portions 22 extending along the second direction Y. At this time, the projections of the first conductor portions 20 in the thickness direction of the display panel 100 can be a mesh structure. Further, in the anti-peeping mode, the light-blocking structures 40 will be attracted to the light-emitting areas A1 by the first conductor portions 20 and present a same or similar mesh structure, wherein the multiple grids in the mesh structure are arranged in an array along the first direction X and the second direction Y, respectively.

In this case, in combination with FIG. 2 and FIG. 5, one light-emitting area A1 is divided by the light-blocking structures 40 into a plurality of sub-areas arranged in an array in the first direction X and the second direction Y. Further, large viewing angle light inclined relative to the second direction Y emitted by each sub-area can be absorbed by part of the light-blocking structures 40 close to the first sub-portions 21, thereby realizing the privacy protection of the display panel 100 in the second direction Y. And large viewing angle light inclined relative to the first direction X emitted by each sub-area can be absorbed by part of the light-blocking structures 40 close to the second sub-portions 22, thereby realizing the privacy protection of the display panel 100 in the first direction X.

Therefore, in the anti-peep mode, it is difficult for the driver to directly observe the image information on the display panel 100 in the second direction Y, and the risk of the display image being obliquely illuminated on the windshield along the first direction X and being reflected by the glass into the driver's eyes can be reduced, thereby further reducing the impact of the display panel 100 on the driver and improving driving safety.

In some embodiments, the first sub-portions 21 are connected with the second sub-portions 22. Optionally, the first sub-portions 21 and the second sub-portions 22 are located in different film layers.

It should be noted that, when there are multiple first sub-portions 21, a single second sub-portion 22 may be connected with only one first sub-portion 21, or a single second sub-portion 22 may be connected with multiple first sub-portions 21 at the same time. Similarly, when there are multiple second sub-portions 22, a single first sub-portion 21 may be connected with only one second sub-portion 22, or a single first sub-portion 21 may be connected with multiple second sub-portions 22 at the same time.

Further, when there are multiple first sub-portions 21, different first sub-portions 21 may be electrically connected with each other, or different first sub-portions 21 may be insulated from each other. Similarly, when there are multiple second sub-portions 22, different second sub-portions 22 may be electrically connected with each other, or different second sub-portions 22 may be insulated from each other.

In the embodiment of the present application, by connecting the first sub-portions 21 with the second sub-portions 22, the first sub-portions 21 and the second sub-portions 22 transmit the same potential. Further, the first sub-portions 21 can be electrically connected with other conductor structures, so that by inputting a specific signal to the first sub-portions 21, the first sub-portions 21 and the second sub-portions 22 connected with each other have a specific potential, or the second sub-portions 22 can be electrically connected with other conductor structures, so that by inputting a specific signal to the second sub-portions 22, the first sub-portions 21 and the second sub-portions 22 connected with each other have a specific potential, which has strong flexibility. In addition, during the design stage of the display panel 100, since one of the first sub-portions 21 and the second sub-portions 22 can be selected to be electrically connected with other external conductor structures, this design helps to reduce the difficulty of conductor layout in the display panel 100.

Furthermore, in some optional embodiments, the first sub-portions 21 and the second sub-portions 22 are arranged in the same layer and comprise the same material, so that during the preparation process, the first sub-portions 21 and the second sub-portions 22 can be prepared and formed together in the same process, thereby simplifying the preparation process of the display panel 100 and improving the preparation efficiency.

In some embodiments, referring to FIG. 6, at least some of the different ones of the first sub-portions 21 are electrically connected with each other.

It should be noted that when multiple first sub-portions 21 simultaneously overlap with the same light-emitting structure 12 in the thickness direction of the display panel 100, the multiple first sub-portions 21 overlapping with the same light-emitting structure 12 can be electrically connected with each other, or the multiple first sub-portions 21 overlapping with different light-emitting structures 12 can be electrically connected with each other, and the embodiments of the present application are not limited thereto.

In the embodiment of the present application, since at least some of the different first sub-portions 21 are electrically connected with each other, as long as one of the first sub-portions 21 can receive the potential signal, the other first sub-portions 21 electrically connected with it can also receive the potential signal. In this way, it is not necessary to connect each first sub-portion 21 with other conductor structures, which helps to simplify the conductor layout difficulty and conductor distribution density of the film layer where the first sub-portions 21 are located, which has strong practicality.

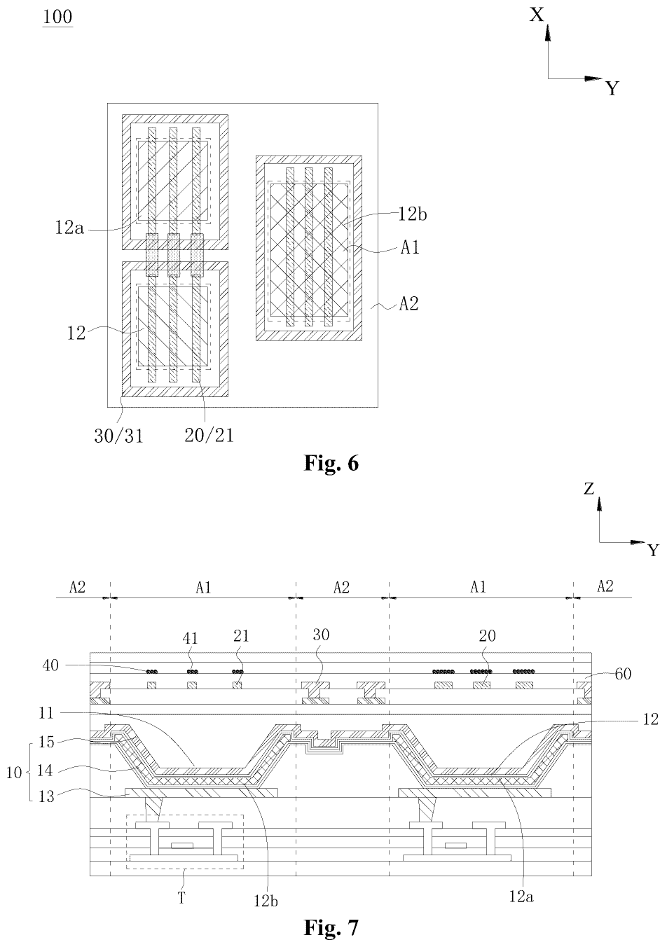

In some embodiments, referring to FIG. 7, the plurality of light-emitting structures 12 comprise first light-emitting structures 12a and second light-emitting structures 12b of different colors (corresponding to different colors), and the width of the first sub-portion 21 overlapping with the first light-emitting structure 12a is greater than the width of the first sub-portion 21 overlapping the second light-emitting structure 12b; and/or, referring to FIG. 8, the number of the first sub-portions 21 overlapping with a single first light-emitting structure 12a is greater than the number of the first sub-portions 21 overlapping with a single second light-emitting structure 12b.

The first light-emitting structures 12a and the second light-emitting structures 12b are light-emitting structures 12 corresponding to different colored lights, and the light-emitting colors corresponding to the first light-emitting structures 12a and the second light-emitting structures 12b are different. The specific light-emitting colors of the first light-emitting structures 12a and the second light-emitting structures 12b are not limited in the present embodiment.

In combination with the above content, it can be known that in the anti-peeping mode, the light-blocking structure 40 will move into the light-emitting areas A1 under the attraction of the first sub-portions 21, and the morphology of at least part of the structures in the light-blocking structures 40 will be the same or similar to that of the first sub-portions 21. Further, if the overlapping areas of the first light-emitting structures 12a and the second light-emitting structures 12b with the corresponding first sub-portions 21 are respectively consistent, then in the anti-peeping mode, the overlapping areas of the first light-emitting structures 12a and the second light-emitting structures 12b with the corresponding light-blocking structure 40 are respectively consistent, that is, the light-shielding degree of the light-blocking structure 40 to the first light-emitting structures 12a and the second light-emitting structures 12b is the same or similar.

Generally, users have different sensitivities to changes in display brightness of different color light-emitting structures 12. Based on this, in the embodiment of the present application, the first sub-portions 21 corresponding to the first light-emitting structures 12a and the second light-emitting structures 12b are not configured in the same way, but the first sub-portions 21 corresponding to the first light-emitting structures 12a and the second light-emitting structures 12b are designed differently to improve the display perception.

Specifically, taking the example of a user who has a high sensitivity when the display brightness of the second light-emitting structures 12b changes, if in the anti-peeping mode, the light-blocking structure 40 blocks or absorbs excessive light from the second light-emitting structures 12b, due to the influence of the light-emitting color of the second light-emitting structures 12b, the user will more easily observe that the display effect of the display panel has changed, thereby affecting the display perception.

In the embodiment of the present application, at least one of the width dimension and the number of the first sub-portions 21 corresponding to the second light-emitting structures 12b is adjusted to be smaller than that of the first sub-portions 21 corresponding to the second light-emitting structures 12b, so that in the anti-peeping mode, the overlapping area of the second light-emitting structures 12b with the corresponding light-blocking structure 40 is smaller than the overlapping area of the first light-emitting structures 12a with the corresponding light-blocking structure 40, thereby reducing the degree of shading of the second light-emitting structures 12b via the light-blocking structure 40, reducing the degree of change in the display brightness corresponding to the second light-emitting structures 12b, and thereby reducing the user's subjective feeling of the change in the effect of the display panel 100, thereby improving the user's corresponding display perception.

It should be noted that the width provided in the embodiment of the present application refers to the average width corresponding to the first sub-portion 21. Specifically, the first sub-portion 21 may have a specific projection area in the thickness direction Z of the display panel, and the projection area divided by the extending length of the first sub-portion 21 is the width of the first sub-portion 21. Further, if the first sub-portion 21 is a strip structure extending along the first direction X, the extending length of the first sub-portion 21 is its dimension in the first direction X. If the first sub-portion 21 comprises first branch portions 211 extending along the first direction X and second sub-portions extending along the second direction Y, the dimension of the first sub-portion 21 is the sum of the dimension of the first branch portions 211 in the first direction X and the dimension of the second branch portions 212 in the second direction Y.

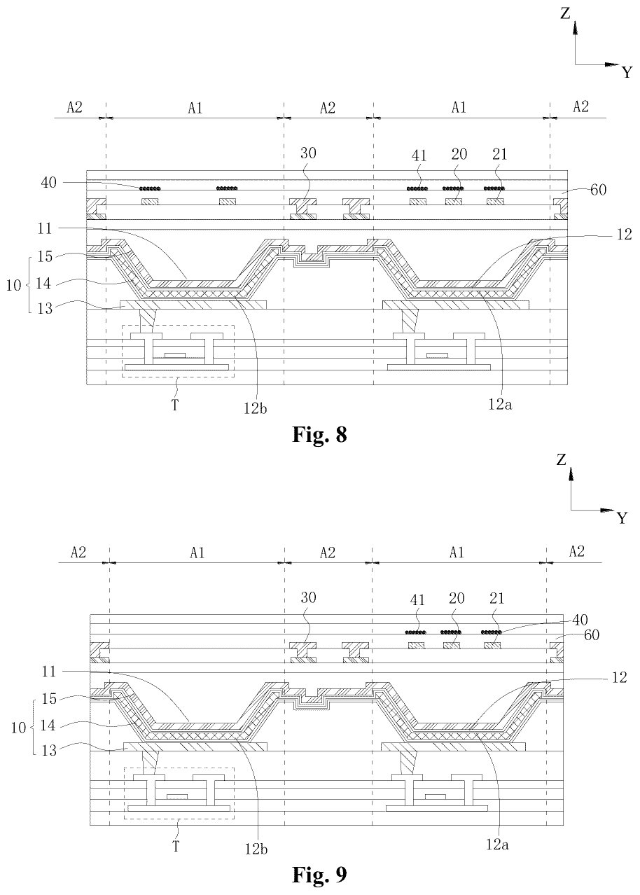

In some embodiments, referring to FIG. 9, in the thickness direction Z of the display panel, the first sub-portions 21 overlap with the first light-emitting structures 12a, and the first sub-portions 21 are located outside the second light-emitting structures 12b.

In the embodiment of the present application, since users are highly sensitive to changes in the display brightness of the second light-emitting structures 12b, the projections of the first sub-portions 21 in the thickness direction Z of the display panel 100 can be set to be located outside the second light-emitting structures 12b, that is, the first sub-portions 21 are staggered with the second light-emitting structures 12b, so as to reduce the influence of the light-blocking structure 40 on the light output efficiency of the second light-emitting structures 12b in the anti-peep mode, thereby reducing the degree of change in the corresponding display brightness of the second light-emitting structures 12b, reducing the user's subjective feeling of the change in the effect of the display panel 100, and improving the viewing experience.

In addition, the first sub-portions 21 overlap with the first light-emitting structures 12a in the thickness direction Z of the display panel. In this design, when the display panel 100 is in the anti-peeping mode, the light-blocking structure 40 can absorb part of the large-viewing angle light from the first light-emitting structures 12a, thereby meeting the anti-peeping requirement of the display panel 100.

In some embodiments, the second light-emitting structures 12b are blue light-emitting structures, and the first light-emitting structure 12a are red light-emitting structures or green light-emitting structures.

Compared with red light and green light, users can more easily feel the change in display effect when the brightness of blue light changes. In view of this, the embodiment of the present application can reduce the width or number of the first sub-portions 21 corresponding to the blue light-emitting structures 12, thereby reducing the brightness change of the blue light of the display panel in the anti-peeping mode and the large-viewing angle mode, improving the user's viewing experience. Alternatively, the first sub-portions 21 can be staggered with the blue light-emitting structures 12 to further reduce the brightness change of the blue light of the display panel in the anti-peeping mode and the large-viewing angle mode, thereby improving the user's viewing experience.

In some embodiments, as shown in FIG. 1, the second conductor portions 30 comprise third sub-portions 31 disposed around the light-emitting areas A1.

The second conductor portion 30 is a conductor structure disposed in the non-light-emitting area A2, and the third sub-portion 31 is at least part of the structure in the second conductor portion 30. The third sub-portions 31 are disposed around the light-emitting areas A1, that is, the projections of the third sub-portions 31 in the thickness direction Z of the display panel 100 are annular structures. The annular structure can have various forms, such as a circular annular structure or a square annular structure.

Optionally, the projections of the third sub-portions 31 in the thickness direction of the display panel 100 may be matched with the projections of the light-emitting areas A1 in the thickness direction of the display panel 100. For example, if the projections of the light-emitting areas A1 in the thickness direction of the display panel 100 are square structures, the projections of the third sub-portions 31 in the thickness direction of the display panel 100 may be square ring structures. If the projections of the light-emitting areas A1 in the thickness direction of the display panel 100 are circular structures, the projections of the third sub-portions 31 in the thickness direction Z of the display panel 100 may be circular ring structures.

In the embodiments of the present application, the third sub-portions 31 having a ring-shaped structure are provided in the second conductor portion 30, thereby reducing the voltage drop corresponding to the second conductor portion 30, which helps to improve the potential consistency at various positions of the second conductor portion 30. At the same time, since the third sub-portions 31 are provided around the light-emitting areas A1, when the display panel 100 needs to be switched from the anti-peeping mode to the large-viewing angle mode, the third sub-portions 31 can apply an attractive force to the light-blocking structure in the light-emitting areas A1 from various positions around the light-emitting areas A1, thereby accelerating the moving speed of the light-blocking structure and improving the switching speed of the display panel 100 in different modes.

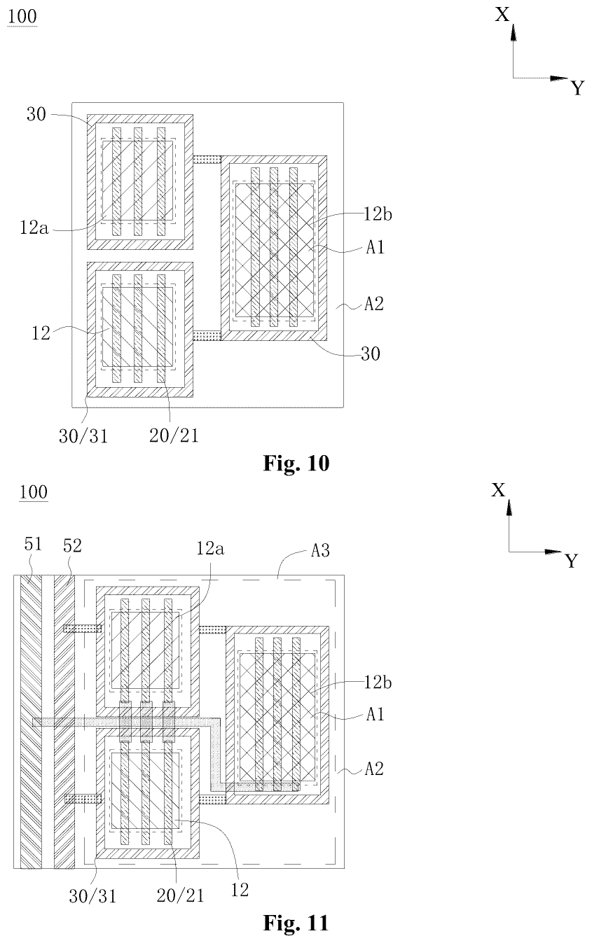

In some embodiments, referring to FIG. 10, at least some of the second conductor portions 30 are electrically connected with each other. Further, at least some of the third sub-portions 31 are electrically connected with each other.

In the thickness direction of the display panel 100, different second conductor portions 30 are respectively arranged on the outer peripheral sides of different light-emitting areas A1, and different second conductor portions 30 are used to attract the light-blocking structures in different light-emitting areas A1 to the non-light-emitting area A2 to meet the need of the display panel 100 of switching from the anti-peep mode to the large-viewing angle mode.

On this basis, in the embodiments of the present application, at least some of the different second conductor portions 30 are further connected with each other, so that at least some of the different second conductor portions 30 can transmit the same potential signal. This design helps to reduce the corresponding voltage drop on the different second conductor portions 30, so that when the display panel 100 switches between different modes, the potential of different second conductor portions 30 can change at the same time, thereby improving the switching rate of the display panel 100 in different modes.

In addition, since at least some of the second conductor portions 30 are electrically connected with each other, it is only necessary to input a specific signal to one of the second conductor portions 30 to make the other second conductor portions 30 have the same specific potential. In other words, for a plurality of second conductor portions 30 that are electrically connected, only one of the second conductor portions 30 need to be electrically connected with other external conductor structures to meet the potential requirements of the plurality of second conductor portions 30, thereby helping to reduce the difficulty of conductor layout inside the display panel 100.

In some embodiments, as shown in FIG. 2, the first conductor portions 20 and the second conductor portions 30 are disposed in the same layer.

In the embodiment of the present application, the first conductor portions 20 and the second conductor portions 30 are disposed in the same film layer, that is, the first conductor portions 20 and the second conductor portions 30 only occupy the space of one film layer in the display panel 100. Compared with the case where the first conductor portions 20 and the second conductor portions 30 are disposed in different film layers, this design can reduce the space occupied by the first conductor portions 20 and the second conductor portions 30 in other film layers, or help reduce the number of film layers in the display panel 100, which is conducive to a lightweight design.

Further optionally, the first conductor portions 20 and the second conductor portions 30 comprise the same material. In this design, the first conductor portions 20 and the second conductor portions 30 can be formed together in the same manufacturing process, thereby simplifying the manufacturing process of the display panel 100 and improving the manufacturing efficiency of the display panel 100.

It should be noted that, in the embodiment of the present application, when the second conductor portions 30 comprise third sub-portions 31 disposed around the light-emitting areas A1, the third sub-portions 31 surround the first conductor portions 20. On this basis, in order to meet the transmission requirements of the potential signal corresponding to the first conductor portions 20, the conductor structures in contact with and connected with the first conductor portions 20 need to be disposed in a different layer from the first conductor portions 20, so as to reduce the risk of contact interference between the conductor structures and the third sub-portions 31, and improve the reliability of the transmission of the potential signals corresponding to the first conductor portions 20 and the second conductor portions 30.

In addition, for the second conductor portions 30, since each second conductor portion 30 is located in the non-light-emitting area A2, and the conductor structure connected with the second conductor portion 30 is also located in the non-light-emitting area A2, the conductor structure usually does not interfere with the first conductor portion 20. On this basis, the second conductor portions 30 and the conductor structures connected thereto can be set in the same layer, or can be set in different layers, which is not limited in the embodiment of the present application. Among them, FIG. 2 shows the situation where the conductor structures connected with the second conductor portions 30 are located on a side of the second conductor portions 30 facing the device layer 10.

In some embodiments, referring to FIG. 11, the display panel 100 further comprises a first potential portion 51 and a second potential portion 52 that are insulated, the first potential portion 51 is electrically connected with the first conductor portions 20, and the second potential portion 52 is electrically connected with the second conductor portions 30.

The first potential portion 51 is a conductor structure for transmitting a specific potential signal to the first conductor portions 20, and the second conductor portion 30 is a conductor structure for transmitting a specific potential signal to the second conductor portions 30. Further, when the display panel 100 remains in the same operating mode, at least one of the first potential portion 51 and the second potential portion 52 can be maintained in a constant potential state. When the display panel 100 switches modes, the first potential portion 51 and the second potential portion 52 can both change their potentials.

The embodiment of the present application does not limit the material composition of the first potential portion 51 and the second potential portion 52. For example, at least one of the first potential portion 51 and the second potential portion 52 may comprise a metal material, and/or at least one of the first potential portion 51 and the second potential portion 52 may comprise a transparent conductive material including indium tin oxide. Optionally, the first potential portion 51 and the second potential portion 52 comprise the same material and are arranged in the same layer, so that the first potential portion 51 and the second potential portion 52 can be formed together in the same preparation process, thereby improving the preparation efficiency of the display panel 100.

In addition, the embodiment of the present application does not limit the positional relationship and shape and size of the first potential portion 51 and the second potential portion 52. For example, the first potential portion 51 can be completely located in the non-light-emitting area A2, or the first potential portion 51 can be completely located in the light-emitting area A1, or the first potential portion 51 can be partially located in the light-emitting area A1 and partially located in the non-light-emitting area A2. And the projection of the first potential portion 51 in the thickness direction Z can be a strip structure, or a block structure, which is not limited in the embodiment of the present application, and the second potential portion 52 is the same.

In the embodiment of the present application, the first potential portion 51 and the second potential portion 52 are provided on the display panel 100, so as to realize the transmission requirement of the potential signal corresponding to the first conductor portion 20 and the second conductor portion 30. On this basis, the positive and negative polarities of the potentials corresponding to the first potential portion 51 and the second potential portion 52 can be adjusted so as to change the direction of the force of the first conductor portion 20 and the second conductor portion 30 relative to the light-blocking structure, so as to realize the switching requirement of the display panel 100 in different modes.

In some embodiments, the first potential portion 51 and the second potential portion 52 are both located in the non-light-emitting area A2.

In the embodiment of the present application, by correspondingly arranging the first potential portion 51 and the second potential portion 52 in the non-light-emitting area A2, the influence of the existence of the first potential portion 51 and the second potential portion 52 on the display effect of the display panel 100 can be reduced, which is beneficial to improving the user's viewing experience.

In some embodiments, the first potential portion 51 and the second potential portion 52 may both be located in a non-display area of the display panel, wherein the non-display area does not comprise a light-emitting area.

Optionally, the first potential portion 51 and the second potential portion 52 both extend along the first direction X and are located in the same film layer. This design allows the first potential portion 51 and the second potential portion 52 to extend in the same direction so that their extension modes do not interfere with each other, thereby integrating the first potential portion 51 and the second potential portion 52 in the same film layer, reducing the occupation of the first potential portion 51 and the second potential portion 52 in other film layer spaces, and having strong practicality. Optionally, the first conductor portions 20, the second conductor portions 30, the first potential portion 51 and the second potential portion 52 are all arranged in the same layer.

In some embodiments, as shown in FIG. 11, part of the adjacent light-emitting areas A1 form a repeated zone A3, and a plurality of repeated zones A3 are arranged in a repeated manner. The first potential portion 51 is located between adjacent repeated zones A3 and is electrically connected with the first conductor portions 20 corresponding to the plurality of light-emitting areas A1 of the same repeated zone A3.

The repeated zone A3 is the common minimum repeating unit of multiple adjacent light-emitting areas A1, that is, the number, light-emitting color type and relative position relationship of the light-emitting areas A1 in each repeated zone A3 remain the same. The embodiment of the present application does not limit the specific number, light-emitting color type and relative position relationship of multiple light-emitting areas A1 in a single repeated zone A3. For example, a single repeated zone A3 may comprise a red light-emitting area for emitting red light, a green light-emitting area for emitting green light, and a blue light-emitting area for emitting blue light.

The multiple repeated zones A3 may be repeatedly arranged along a single direction, or the multiple repeated zones A3 may be repeatedly arranged along multiple directions. For example, the multiple repeated zones A3 may be repeatedly arranged along the first direction X and the second direction Y.

In the embodiment of the present application, the first potential portions 51 are arranged between adjacent repeated zones A3, and a single first potential portion 51 can be connected with the first conductor portions 20 corresponding to multiple light-emitting areas A1 of the adjacent same repeated zone A3. This layout can reduce the distance between the first potential portion 51 and the corresponding electrically connected first conductor portion 20, reduce the difficulty of connection between the two, and one first potential portion 51 can simultaneously control the first conductor portions 20 corresponding to multiple light-emitting areas A1 of the same repeated subarea A3, thereby reducing the number of first potential portions 51. In addition, this can ensure that the relative position relationship of the light-blocking structures at different light-emitting areas A1 in the same repeated zone A3 remains consistent at the same time, thereby improving the display reliability of the display panel 100.

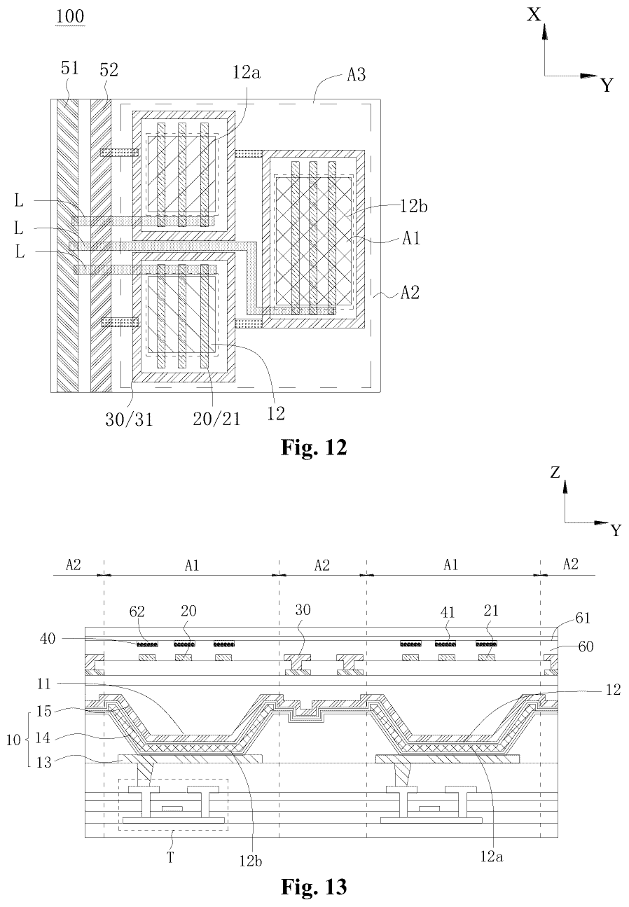

It should be noted that the multiple first conductor portions 20 corresponding to the multiple light-emitting areas A1 of the same repeated zone A3 can be connected with each other, so that a single first potential portion 51 can be electrically connected with the first conductor portions 20 corresponding to the multiple light-emitting areas A1 of the same repeated zone A3. Alternatively, referring to FIG. 12, the multiple first conductor portions 20 corresponding to the multiple light-emitting areas A1 of the same repeated zone A3 may not be directly connected. In this case, the first potential portion 51 may comprise multiple branch structures L connected with different first conductor portions 20 respectively, so that a single first potential portion 51 can be electrically connected with the first conductor portions 20 corresponding to the multiple light-emitting areas A1 of the same repeated zone A3.

In some embodiments, at least some of the first conductor portions 20 located in the same light-emitting area A1 have different potentials.

In the embodiment of the present application, for at least some of the different first conductor portions 20 in different light-emitting areas A1, there are differences in their potential at the same time, so that a voltage step can be formed between the different first conductor portions 20. The voltage step helps to move the light-blocking structures 40 faster, thereby improving the switching rate of the display panel 100 in different modes.

In some embodiments, referring to FIG. 13, the display panel 100 further comprises a light-transmitting layer 60 disposed on the light-emitting side 11 of the device layer 10, the light-transmitting layer 60 has a first surface 61 away from the device layer 10, a plurality of recessed portions 62 formed by the first surface 61 recess inwardly, and the light-blocking structures 40 can be accommodated in the recessed portions 62. In the thickness direction Z of the display panel 100, at least one of the first conductor portions 20 and the second conductor portions 30 is overlapped with the recessed portion 62.

The light-transmitting layer 60 is a film layer structure including a transparent material and located on the light-emitting side 11 of the device layer 10, the light-transmitting layer 60 may be located on a side of the first conductor portions 20 facing the device layer 10, or the light-transmitting layer 60 may be located on a side of the first conductor portions 20 away from the device layer 10. Similarly, the light-transmitting layer 60 may be located on a side of the second conductor portions 30 facing the device layer 10, or the light-transmitting layer 60 may be located on a side of the second conductor portions 30 away from the device.

The first surface 61 is a surface of the light-transmitting layer 60 away from the device layer 10. The light-transmitting layer 60 is provided with a plurality of recessed portions 62 on the first surface 61. The recessed portions 62 can be formed by etching or other processes. In the thickness direction Z of the display panel 100, at least one of the first conductor portions 20 and the second conductor portions 30 overlaps with the recessed portions 62, that is, some of the recessed portions 62 are located in the light-emitting areas A1, and some of the recessed portions 62 are located in the non-light-emitting areas A2.

In the embodiments of the present application, a plurality of recessed portions 62 are provided in the light-transmitting layer 60, and the plurality of recessed portions 62 are provided in the light-emitting areas A1 and the non-light-emitting areas A2 respectively. Thus, in the anti-peeping mode, the positions of the light-blocking structures 40 are limited by the recessed portions 62 in the light-emitting areas A1, and in the large-viewing angle mode, the position of the light-blocking structures 40 are limited by the recessed portions 62 in the non-light-emitting areas A2. This reduces the risk of displacement of the light-blocking structures 40 in the anti-peeping mode and the large-viewing angle mode, thereby improving display reliability.

It should be noted that, in the embodiments of the present application, since the presence of the recessed portions 62 can limit the positions of the light-blocking structures 40, when the display panel 100 is in the anti-peeping mode, there need not be a constant potential in the first conductor portions 20 for limiting the positions of the light-blocking structures 40. Similarly, in the large-viewing angle mode, there need not be a constant potential in the second conductor portions 30 for limiting the positions of the light-blocking structures 40. In other words, the first conductor portions 20 and the second conductor portions 30 only need to have a specific potential when the display panel 100 changes to the corresponding working mode, so as to drive the light-blocking structures 40 to move between the light-emitting areas A1 and the non-light-emitting areas A2.

In some embodiments, the light-transmitting layer 60 comprises an insulating material covering at least one of the first conductor portions 20 and the second conductor portions 30.

In the embodiments of the present application, the light-transmitting layer 60 is located on the side of the first conductor portions 20 and the second conductor portions 30 away from the device layer 10. In addition to limiting the positions of the light-blocking structures 40, the light-transmitting layer 60 can also insulate and separate the first conductor portions 20 from the second conductor portions 30, thereby reducing signal interference between the first conductor portions 20 and the second conductor portions 30. Furthermore, since the film layer structure for limiting the position of the light-blocking structures 40 and the film layer structure for insulating and separating the first conductor portions 20 from the second conductor portions 30 are integrated into one film layer, it helps to reduce the number of film layers inside the display panel 100, which is conducive to a lightweight design.

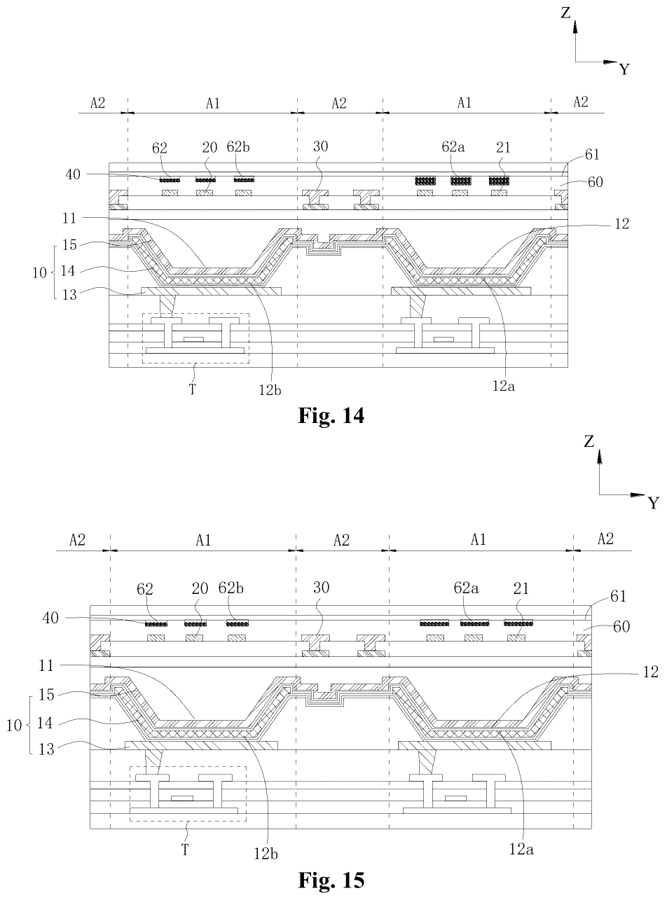

In some embodiments, referring to FIG. 14, the light-emitting areas A1 comprise light-emitting structures 12, which comprise first light-emitting structures 12a and second light-emitting structures 12b of different colors, the plurality of recessed portions 62 comprise first recessed portions 62a overlapping with the first light-emitting structures 12a in a thickness direction Z of the display panel, and second recessed portions 62b overlapping with the second light-emitting structures 12b; wherein the depth of the first recessed portion 62a is greater than the depth of the second recessed portion 62b; and/or, referring to FIG. 15, the width of the first recessed portion 62a is greater than the width of the second recessed portion 62b.

Both the first recessed portion 62a and the second recessed portion 62b can be used to accommodate light-blocking particles. In the anti-peeping mode, the light-blocking structures 40 corresponding to the first light-emitting structures 12a will be located in the first recessed portions 62a, and the light-blocking structures 40 corresponding to the second light-emitting structures 12b will be located in the second recessed portions 62b. Among them, the size and shape of the light-blocking structure 40 located in the first recessed portion 62a are usually affected by the size and shape of the first recessed portion 62a. On this basis, if the width of the first recessed portion 62a is larger, the corresponding width of the light-blocking structure 40 located in the first recessed portion 62a is also larger, and the degree of light shielding for the first light-emitting structure 12a is also greater. If the depth of the first recessed portion 62a is larger, the size of the light-blocking structure 40 located in the first recessed portion 62a in the thickness direction Z of the display panel is also larger, and the degree of light shielding for the first light-emitting structure 12a is also greater. The light-blocking structure 40 located in the second recessed portion 62b is similar to this, and the embodiments of the present application will not be repeated.

Combined with the above content, it can be known that the user has different sensitivity to the display brightness changes of different color light-emitting structures 12. If in the anti-peeping mode, the light-blocking structures 40 blocks or absorbs too much light from the second light-emitting structures 12b, due to the influence of the light color of the second light-emitting structures 12b, the user will more easily observe that the display effect of the display panel changes, thereby affecting the display perception.

In view of this, the embodiment of the present application has limited the size of the second recessed portion 62b, so that at least one of the width and depth of the second recessed portion 62b is smaller than the first recessed portion 62a, thereby reducing the degree of light shielding of the second light-emitting structures 12b of the light-blocking structures 40 located in the second recessed portions 62b in the anti-peep mode, reducing the degree of change in display brightness corresponding to the second light-emitting structures 12b, and thereby reducing the user's subjective perception of the change in the effect of the display panel 100, thereby improving the user's corresponding display perception.

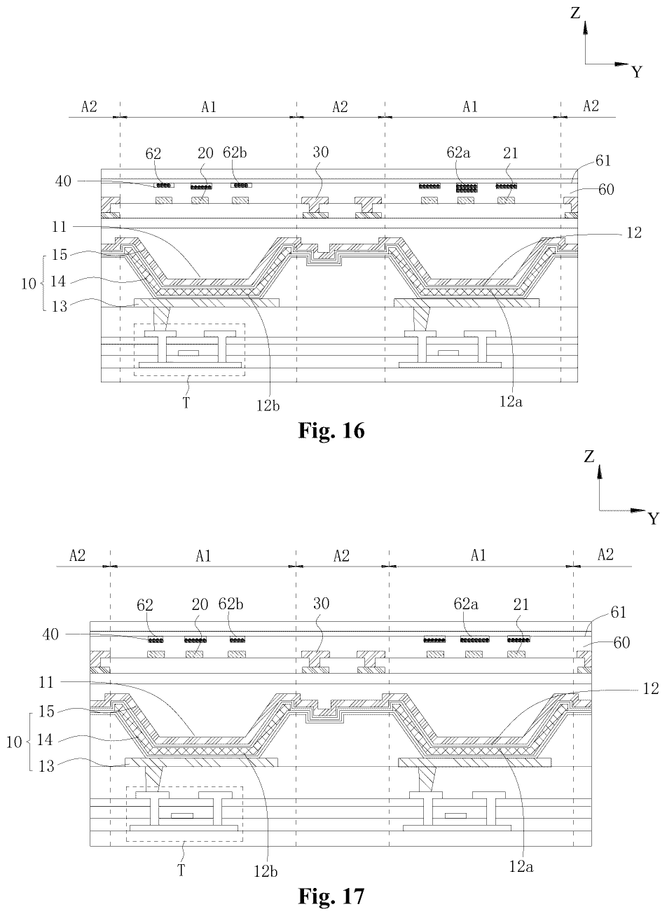

In some embodiments, referring to FIG. 16, in the thickness direction Z of the display panel, multiple recessed portions 62 are overlapped with the same light-emitting area A1, wherein the corresponding depths of different recessed portions 62 tend to gradually increase in the direction from the peripheral edge to the center of the light-emitting area A1; and/or, referring to FIG. 17, the corresponding widths of different recessed portions 62 tend to gradually increase.

In the embodiments of the present application, one light-emitting area A1 is provided with a plurality of recessed portions 62. In the direction from the peripheral edge to the center of the light-emitting area A1, at least one of the width and the depth is different among different recessed portions 62. The peripheral edge of the light-emitting area A1 mentioned here refers to the position where the light-emitting area A1 intersects with the non-light-emitting area A2. On this basis, in the direction from the peripheral edge to the center of the light-emitting area A1, the depths corresponding to different recessed portions 62 show a trend of gradually increasing, that is, the closer to the center of the light-emitting area A1, the greater the depth corresponding to the recessed portion 62, and the closer to the non-light-emitting area A2, the smaller the depth of the recessed portion 62. Similarly, in the direction from the peripheral edge to the center of the light-emitting area A1, the widths corresponding to different recessed portions 62 show a trend of gradually increasing, that is, the closer to the center of the light-emitting area A1, the greater the width corresponding to the recessed portion 62, and the closer to the non-light-emitting area A2, the smaller the width of the recessed portion 62.

Furthermore, the larger the width corresponding to the recessed portion 62, the larger the width of the light-blocking structure 40 in the recessed portion 62; the larger the depth corresponding to the recessed portion 62, the larger the size of the light-blocking structure 40 in the recessed portion 62 in the thickness direction Z of the display panel 100. Therefore, by setting the recessed portion 62 at the center of the light-emitting area A1 to be deeper or wider, the corresponding light-shielding effect of the light-blocking structure 40 at the center of the light-emitting area A1 is stronger, thereby improving the corresponding anti-peeping effect of the display panel 100.

In some embodiments, the first conductor portion 20 comprises a transparent conductive material.

In the embodiment of the present application, considering that the first conductor portions 20 are arranged corresponding to the light-emitting areas A1, in order to reduce the influence of the first conductor portions 20 on the light-emitting effect, the material of the first conductor portion 20 is set to comprise a transparent conductive material, so that the first conductor portions 20 can meet the function of attracting and repelling the light-blocking structures 40, so that at least part of the light can pass through the first conductor portions 20, thereby improving the display effect. Optionally, the first conductor portions 20 comprise indium tin oxide.

In some embodiments, as shown in FIG. 2, the light-blocking structures 40 comprise electrophoretic particles 41.

In the embodiment of the present application, the electrophoretic particles 41 are charged particles that move toward an electrode with an opposite electrical property under the action of an electric field, and by providing the light-blocking structures 40 with the electrophoretic particles 41, the display panel 100 can be switched between different modes by moving the electrophoretic particles 41 in the light-emitting areas A1 and the non-light-emitting areas A2, which has strong practicality. The light-blocking structures can be provided in the liquid film layer.

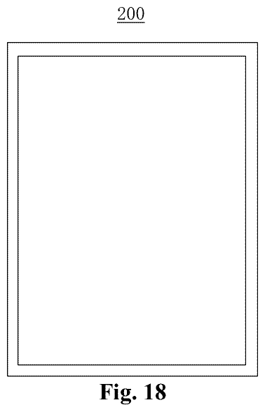

In the second aspect, referring to FIG. 18, an embodiment of the present application provides a display device 200, which comprises the display panel in any of the aforementioned embodiments.

It should be noted that the display device 200 provided in the embodiment of the present application has the beneficial effects of the display panel in any one of the aforementioned embodiments. Referring to the aforementioned description of the beneficial effects of the display panel for details, which will not be described in detail in the embodiment of the present application.

Although the embodiments disclosed in this application are as above, the contents described are only embodiments adopted for facilitating the understanding of this application and are not intended to limit the present invention. The skilled in the art to which this application belongs can make any modifications and changes in the form and details of implementation without departing from the spirit and scope disclosed in this application, but the scope of protection of this application shall still be subject to the scope defined in the attached claims.

The above are only specific implementations of the present application. The skilled in the art can clearly understand that for the convenience and simplicity of description, the replacement of other connection methods described above can refer to the corresponding process in the aforementioned method embodiment, and will not be repeated here. It should be understood that the protection scope of the present application is not limited to this. The skilled in the art familiar with the technical field can easily think of various equivalent modifications or replacements within the technical scope disclosed in this application, and these modifications or replacements should be comprised in the protection scope of the present application.

What is claimed is:

1. A display panel, comprising:
a plurality of light-emitting areas, and non-light-emitting areas located between adjacent ones of the light-emitting areas;
a device layer;
at least one first conductor portion, at least partially located in the light-emitting areas and arranged on a light-emitting side of the device layer;
at least one second conductor portion, located in the non-light-emitting areas and arranged on the light-emitting side of the device layer, the at least one second conductor portion being insulated from the at least one first conductor portion;
at least one light-blocking structure, disposed on the light-emitting side of the device layer and configured to be attracted or repelled by the at least one first conductor portion and the at least one second conductor portion to transfer between the light-emitting areas and the non-light-emitting areas.

2. The display panel of claim 1, wherein the light-emitting areas comprise light-emitting structures, and the at least one first conductor portion comprises at least one first sub-portion;
the at least one first sub-portion overlap with the light-emitting structures in a thickness direction of the display panel.

3. The display panel of claim 2, wherein a plurality of the first sub-portions overlap with one of the light-emitting structures in the thickness direction of the display panel.

4. The display panel of claim 2, wherein a plurality of the first sub-portions extend along a first direction and arranged side by side in a second direction; or
the at least one first sub-portion comprise a first branch portion extending along the first direction and a second branch portion extending along the second direction,
the first direction, the second direction and the thickness direction intersecting each other.

5. The display panel of claim 2, wherein the at least one first conductor portion comprise a first sub-portion extending along a first direction and a second sub-portion extending along a second direction, the first sub-portion and the second sub-portion of one first conductor portion overlapping with one of the light-emitting structures in the thickness direction,
the first direction, the second direction and the thickness direction intersecting each other.

6. The display panel of claim 5, wherein the first sub-portion is connected with the second sub-portion.

7. The display panel of claim 2, wherein the at least one first conductor portion comprises a plurality of first sub-portions, at least part of the first sub-portions being electrically connected with each other.

8. The display panel of claim 2, wherein a plurality of the light-emitting structures comprise first light-emitting structures and second light-emitting structures of different colors;
widths of the first sub-portions overlapping with the first light-emitting structures are greater than widths of the first sub-portions overlapping with the second light-emitting structures; or,
the number of the first sub-portions overlapping with a single one of the first light-emitting structures is greater than the number of the first sub-portions overlapping with a single one of the second light-emitting structures.

9. The display panel of claim 2, wherein a plurality of the light-emitting structures comprise first light-emitting structures and second light-emitting structures of different colors;
in the thickness direction of the display panel, the first sub-portions overlap with the first light-emitting structures, and the first sub-portions are located outside the second light-emitting structures.

10. The display panel of claim 8, wherein the second light-emitting structures are blue light-emitting structures, and the first light-emitting structures are red light-emitting structures or green light-emitting structures.

11. The display panel of claim 9, wherein the second light-emitting structures are blue light-emitting structures, and the first light-emitting structures are red light-emitting structures or green light-emitting structures.

12. The display panel of claim 1, wherein the at least one second conductor portion each comprise a third sub-portion disposed around the light-emitting areas.

13. The display panel of claim 1, wherein the display panel comprises a plurality of second conductor portions, at least some of the second conductor portions being electrically connected with each other.

14. The display panel of claim 1, wherein the display panel further comprises first potential portions and second potential portions insulated from each other, the first potential portions being electrically connected with the at least one first conductor portion, and the second potential portions being electrically connected with the at least one second conductor portion.

15. The display panel of claim 1, wherein at least some of the first conductor portions located in the same light-emitting area have different potentials.

16. The display panel of claim 1, wherein the display panel further comprises a light-transmitting layer arranged on the light-emitting side of the device layer, the light-transmitting layer having a first surface away from the device layer and a plurality of recessed portions depressed inward from the first surface, the light-blocking structures being accommodated in the recessed portions; and
in a thickness direction of the display panel, at least the first conductor portions or at least the second conductor portions overlaps with the recessed portions.

17. The display panel of claim 16, wherein the light-emitting areas comprise light-emitting structures including first light-emitting structures and second light-emitting structures of different colors, and a plurality of the recessed portions include first recessed portions overlapping with the first light-emitting structures in the thickness direction of the display panel and second recessed portions overlapping with the second light-emitting structures;
depths of the first recessed portions are greater than depths of the second recessed portions; or,
widths of the first recessed portions are greater than widths of the second recessed portions.

18. The display panel of claim 16, wherein a plurality of the recessed portions overlap with one of the light-emitting areas in the thickness direction;
in a direction extending from peripheral edges to centers of the light-emitting areas, depths of the recessed portions tend to gradually increase, or widths of the recessed portions tend to gradually increase.

19. The display panel of claim 1, wherein the light-blocking structures comprise electrophoretic particles.

20. A display device, comprising a display panel, comprising:
a plurality of light-emitting areas, and non-light-emitting areas located between adjacent ones of the light-emitting areas;
a device layer;
at least one first conductor portion, at least partially located in the light-emitting areas and arranged on a light-emitting side of the device layer;
at least one second conductor portion, located in the non-light-emitting areas and arranged on the light-emitting side of the device layer, the second conductor portions being insulated from the first conductor portions;
at least one light-blocking structure, disposed on the light-emitting side of the device layer and configured to be attracted or repelled by the first conductor portions and the second conductor portions to transfer between the light-emitting areas and the non-light-emitting areas.
